(19) United States
(12) Patent Application Publication
(10) Pub. No.: US 2012/0200299 A1
(43) Pub. Date: Aug. 9, 2012

(54) Handheld Electrical Testing Device

(76) Inventor: Arthur David Stanton, Garland, TX (US)

(21) Appl. No.: 13/366,294

(22) Filed: Feb. 4, 2012

Related U.S. Application Data
(60) Provisional application No. 61/439,555, filed on Feb. 4, 2011.

(51) Int. Cl. G01R 31/02

(52) U.S. Cl. 324/508

(57) ABSTRACT

A handheld electrical testing device is provided. The handheld electrical testing device includes a housing, electrical circuits located inside the housing for testing electrical components and sending results of the electrical test to a display, a display located on the surface of the housing, a selector switch located on the surface of the housing, a battery compartment wherein a DC battery can be placed, test leads that can be inserted into the housing connected to the internal circuitry within the housing and that can be clamped onto electrical components of a structure. The handheld electrical testing device also includes cubes that can be plugged into electrical outlets, the cubes including test leads that can be clamped by the test leads that are plugged into the housing.

This application claims the benefit under 35 U.S.C. §119(e) of U.S. Provisional Patent Application No. 61/439,555 filed on Feb. 4, 2011 in the United States Patent and Trademark Office entitled “A hand held testing device allowing for the testing of electrical panels, wiring, switches, outlets, lighting and any other electrical components that are part of the fabric of a residential or commercial building framework before live AC current is applied to the system.’

### BACKGROUND

1. Field of the Invention

The present invention relates generally to devices used to test electrical circuits and in particular to a handheld electrical testing device allowing for the testing of electrical panels, wiring, switches, outlets, lighting, and any other electrical components that are part of the fabric of a residential or commercial building's framework before live alternating current (AC) is applied to the system.

Electric breaker panels, wiring, switches, outlets, lighting and the like are part of the fabric of a residential or commercial building's framework and much of it often runs through complex framing structures, foundation, ceilings, walls or conduit. Once the electrical system is installed in a building the electrical components within the building must be tested to ensure the integrity of the electrical system.

The current invention is a handheld device that can be used during the construction phase of a structure, prior to AC power being applied to the breaker panel and before a finished wall is installed, which allows for the safe and thorough testing of installed wiring and related devices. The current invention detects any potential electrical shorts prior to completing the build-out of the interior structures that allows the electrical system to be thoroughly tested.

2. Description of Related Art

Safety standards require that electrical components that a person may be exposed to have to be deenergized before and while a person works on or near them. Therefore, it is a conventional practice for residential and commercial electricians to wait until the newly installed circuit wiring and electrical equipment is covered by wall and ceiling enclosures before testing for live circuits and accuracy (correct circuit grouping, sequencing, etc.). The main breaker panel is powered with live alternating current power, and then the individual breaker switches are activated. The conventional practice is unsafe since the testing is performed with live current, high voltage, and involves a huge amount of potential rework (i.e. opening finished walls and reconstructing them) when the circuits are shorted due to incorrect termination and other wiring mistakes during installation. This damage sometimes permeates (due to the melting of wires after a short) to surrounding wires after a short has occurred from surrounding circuits in the same conduit. Testing is never performed due to the lack of existence of an appropriate device to test prior to live current being applied to the circuits to prevent such costly occurrence which is wide spread (Circuit breakers often trip during this testing phase due to electrical shorts).

The powering of the breaker panel of a structure through a device such as the present invention has been absent within the industry. There has been a long felt and unsatisfied need to test such circuits both thoroughly and safely prior to energizing the circuits with live AC current. Currently AC voltage is applied to the circuits to perform checks upon the electrical framework exposing electricians to potential serious injury or death to electricians working on the circuit. The electrical industry requires licensed journeyman, electrician to perform this risky task with live AC current. This device eliminates the need to have a licensed journeyman, electrician (professional) to perform the task of testing the circuits thoroughly and safely which will cut labor costs considerably for the companies.

Prior to the present invention the industry did not have a way to test the health of the circuits without energizing the panel with live AC voltage. It has been unobvious to electricians within the electrical field who mostly work with AC current to test with DC voltage on an AC circuit. This is because generally most AC electricians work with and are trained only with AC current. Individuals who go to school to become a journeymen or licensed electrician are trained only within the field of AC power. Moreover, these AC electricians both scholastically and on the job have been taught away from thinking about applying DC voltage to AC circuits. Further, because the AC electricians have limited and sometimes no exposure to working with DC power it made the idea and method of testing with DC voltage upon an AC circuit inconceivable to them.

The failure to have such a device puts a huge cost (time and resources) on business owners today. The AC voltage is applied after the circuits are wired up and setting up the enclosures over them. In the event shorts exist, the enclosures are undone and rewiring is required.

A need exists, therefore, for an electrical testing device that will allow for the safe testing of the electrical components of a structure before the main breaker panel is powered with live AC power.

A need also exists for an electrical testing device that is compact so that it can be carried around a structure to test the various electrical components of a structure.

All references cited herein are incorporated by reference to the maximum extent allowable by law. To the extent a reference may not be fully incorporated herein, it is incorporated by reference for background purposes and indicative of the knowledge of one of ordinary skill in the art.

### BRIEF SUMMARY OF THE INVENTION

The problems presented in existing methods of testing electrical components of a structure are solved by the handheld electrical testing device of the present invention. In accordance with one embodiment of the present invention, a handheld electrical testing device is provided. The handheld electrical testing device includes a housing, electrical circuits located inside the housing for providing a safe amount of current to an electrical component, testing electrical components, and sending results of the electrical test to a display, a display located on the surface of the housing, a selector switch located on the surface of the housing for a variety of tests, a battery compartment wherein a DC battery can be placed and used to provide power to the device as well as a safe amount of current to an electrical component, test leads that can be inserted into the housing connected to the internal circuitry within the housing and that can be clamped onto electrical components of a structure to provide a safe amount of current as well as test an electrical component. In accordance with another embodiment of the present invention, a handheld electrical testing device is provided as above, but also includes cubes that can be plugged into electrical outlets that have been provided a safe amount of current, the cubes including electrical circuits located inside the cube so that the electrical outlet can be tested, and test leads that can be clamped onto electrical components that have been safely energized by the handheld electrical testing device so that the electrical component can be tested.

The use of this handheld electrical testing device allows a person who needs to test the electrical components of a structure to provide a small amount of current to the electrical component so that the circuit can be tested to ensure it is wired correctly with the ease of walking to each electrical component and performing the test and without having to provide a potentially dangerous and damaging amount of power to the entire electrical system.

Other objects, features, and advantages of the present invention will become apparent with reference to the drawings and detailed description that follow.

### BRIEF DESCRIPTION OF THE DRAWINGS

FIG. 1 is a pictorial representation of a top view of the handheld electrical testing device in accordance with an illustrative embodiment.

FIG. 2 is a pictorial representation of a circuit contained within the housing of the handheld electrical testing device in accordance with an illustrative embodiment.

FIG. 3 is a photograph of the handheld electrical testing device in accordance with an illustrative embodiment.

FIG. 4 is a pictorial representation of a two-pronged cube used with the handheld electrical testing device in accordance with an illustrative embodiment.

FIG. 5 is a pictorial representation of a three-pronged cube used with the handheld electrical testing device in accordance with an illustrative embodiment.

FIG. 6 is a pictorial representation of a circuit contained within the cube to be used with the handheld electrical testing device in accordance with an illustrative embodiment.

FIG. 7 is a pictorial representation of a circuit contained within the housing of the handheld electrical testing device in accordance with an illustrative embodiment.

FIG. 8 is a photograph of the handheld electrical testing device in accordance with an illustrative embodiment.

### DETAILED DESCRIPTION OF THE PREFERRED EMBODIMENT

All references cited herein are incorporated by reference to the maximum extent allowable by law. To the extent a reference may not be fully incorporated herein, it is incorporated by reference for background purposes and indicative of the knowledge of one of ordinary skill in the art.

In the following detailed description of the preferred embodiments, reference is made to the accompanying drawings which form a part hereof, and in which is shown by way of illustration specific preferred embodiments in which the invention may be practiced. These embodiments are described in sufficient detail to enable those skilled in the art to practice the invention, and it is understood that other embodiments may be utilized and that logical mechanical and electrical changes may be made without departing from the spirit or scope of the invention. To avoid detail not necessary to enable those skilled in the art to practice the invention, the description may omit certain information known to those skilled in the art. The following detailed description is, therefore, not to be taken in a limiting sense, and the scope of the present invention is defined only by the appended claims.

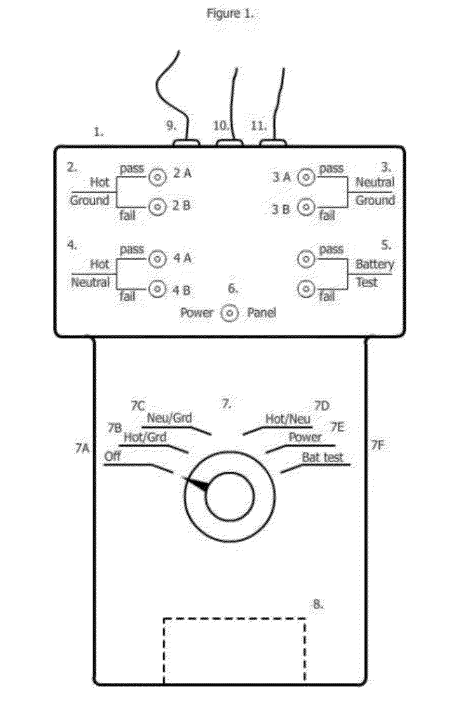

With reference now to the figures, and in particular, with reference to FIGS. 1-8, exemplary representations of the handheld electrical testing device and its electrical circuitry are provided. It should be appreciated that FIGS. 1-8 are only exemplary and are not intended to assert or imply any limitation with regard to the way different embodiments may be practiced. Many modifications to the depicted embodiments may be made.

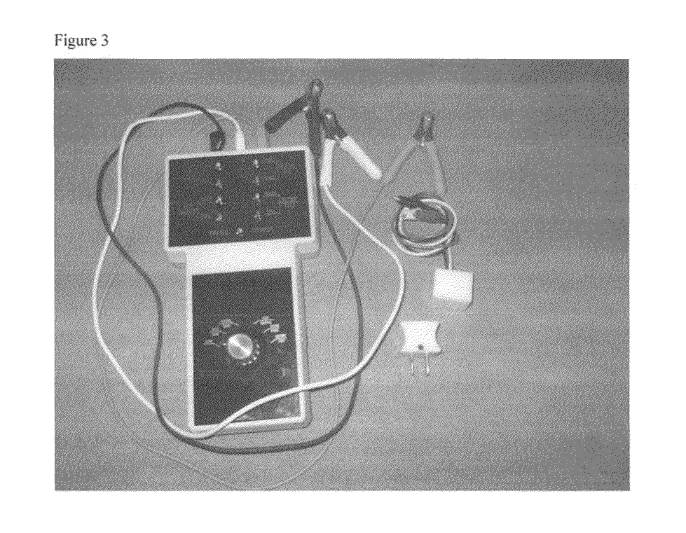

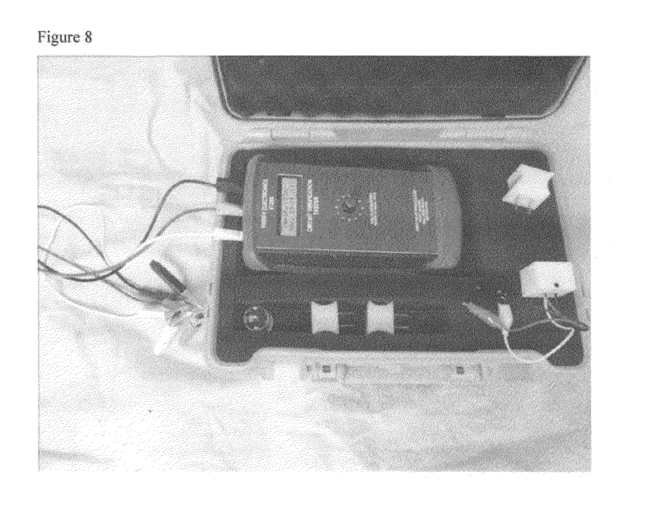

FIG. 1 is a pictorial representation of a top view of the handheld electrical testing device in accordance with an illustrative embodiment. FIG. 3 is a photograph of the handheld electrical testing device in accordance with an illustrative embodiment. FIG. 8 is a photograph of the handheld electrical testing device in accordance with an illustrative embodiment.

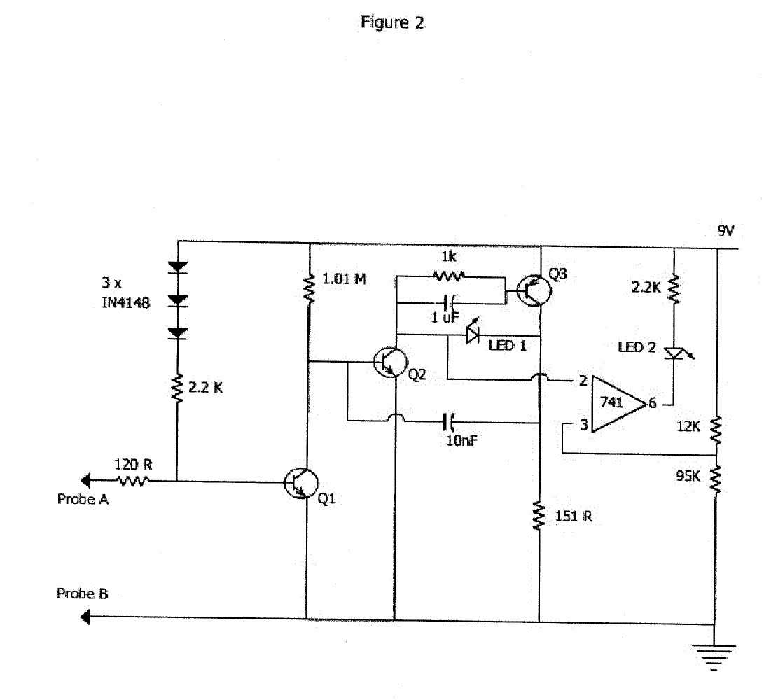

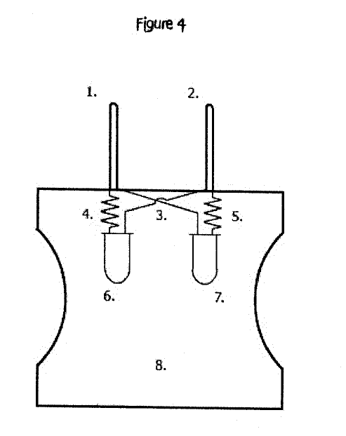

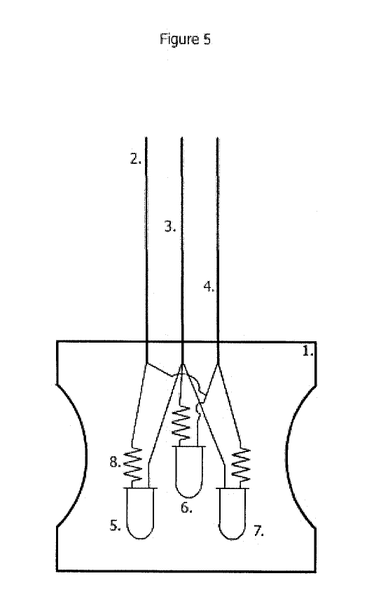

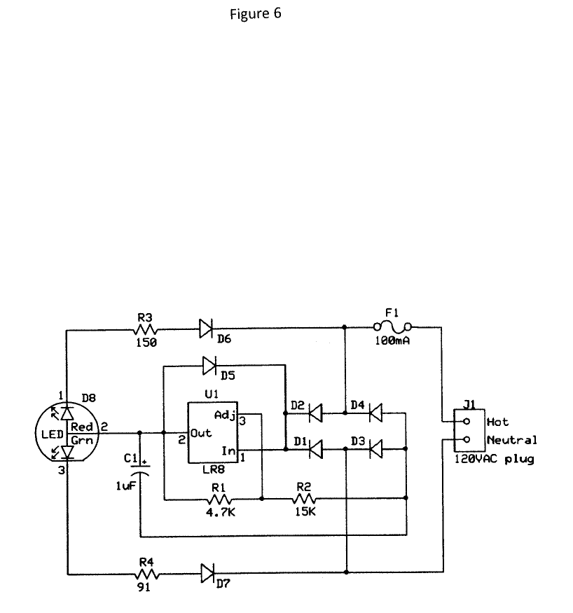

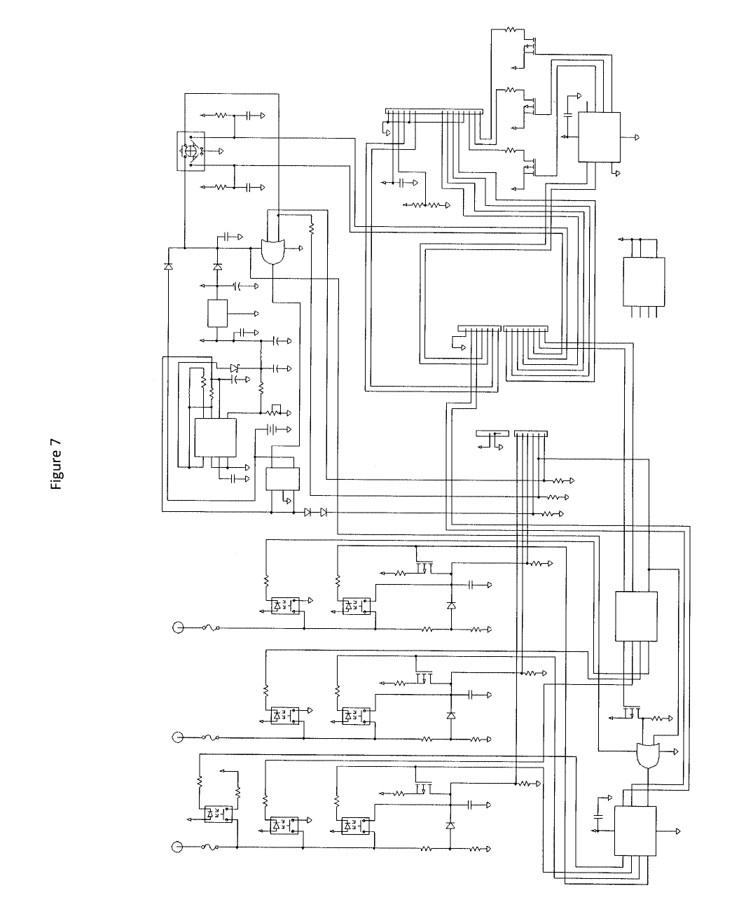

In accordance with one embodiment of the present invention, a handheld electrical testing device 1 is provided. The handheld electrical testing device 1 includes a housing, wherein electrical circuits as depicted in FIG. 2 and FIG. 7 are located inside the housing for providing a safe amount of current to an electrical component, testing electrical components, and sending results of the electrical test to a display. The handheld electrical testing device 1 includes a display located on the surface of the housing that displays a variety of information, such as the results of an electrical test of an electrical component, whether the battery is good or not, and whether an electrical component has live current. The display may simply be one or more different colored lights or a liquid crystal display, or a combination of both. The handheld testing device 1 also includes a selector switch 7 located on the surface of the housing for a variety of tests. The selector switch 7 is turned to a certain location which activates certain electrical circuits within the device depending on the test the user desires to run. The handheld testing device 1 also includes a battery compartment wherein a DC battery can be placed and used to provide power to the device as well as a safe amount of current to an electrical component. The handheld testing device 1 also includes test leads that can be inserted into the housing connected to the internal circuitry within the housing and that can be clamped onto electrical components of a structure to provide a safe amount of current as well as test an electrical component. In accordance with another embodiment of the present invention, a handheld electrical testing device 1 is provided as above, but also includes cubes as depicted in FIG. 4 and FIG. 5, with electrical circuitry as depicted in FIG. 6, that can be plugged into electrical outlets that have been provided a safe amount of current. The cubes may also include test leads that can be clamped onto electrical components that have been safely energized by the handheld electrical testing device 1 so that the electrical component can be tested.

The hand held testing device 1 embodies three basic tests to validate the health of the circuit. The device is activated/turned on after moving the selector switch 7 from the off position to any one of the available test selection positions. The possible positions of the selector switch 7 includes Off selection 7A which turns the device off, Hot/Ground selection 7B to test the short between the hot and the ground, Neutral/Ground selection 7C to test the short between the neutral and the ground, Hot/Neutral selection 7D to test the short between the hot and the neutral, Power selection 7E to power the electrical component, Battery Test selection 7F to test the internal battery power.

Upon choosing one of the three test selection positions (7B, 7C, or 7D as listed above) the handheld electrical testing device 1 will immediately provide the user pass/fail information associated with each of the three tests on the display. The information associated with the health (pass/fail) of the individual circuit is brought to the user's attention by an indicator device (such as LED, LCD, audio) on top of the device. When the display is used with LED lights, pass is indicated by the color green and a fail is indicated by a red color. When the display is used with an LCD display, the display may light a certain color as well as display the status of the device. For example, for a pass test result of a hot and neutral test, the LCD display may read ‘Hot/Neutral’ and ‘Pass” as well as display a green color.

The battery test of the handheld electrical testing device 1, which is powered by an internal battery circuit, validates the internal battery power and provides the results (pass/fail) on the display.

The power panel indicator is only lit when the selector switch 7 is placed in the power selection position. This power panel selection enables the handheld electrical testing device 1 to apply current from the handheld electrical testing device 1 to the electrical component through two of the three test leads 9, 10, 11. This lets the user know that direct current is flowing from the device to the electrical component.

Absent discovery of any shorts in the circuits the handheld electrical testing device 1 will further evaluate that the pre-determined outlets and electrical devices are on the proper circuit and have not been inadvertently crossed wired. This will be accomplished in two steps. First, the handheld electrical testing device 1 will be utilized to energize an electrical component with direct current voltage which will allow the direct current voltage to flow from the handheld electrical testing device 1 to the entire electrical panel. Once the electrical panel is energized with this direct current voltage, then the individual circuit breakers on the electrical panel and their associated circuits can be tested as well as the outlets or other junction boxes on that circuit as well. Second, the two pronged white cube or the three lead white cube will be connected to the outlet or junction boxes of the circuit to be tested. The health of the wiring to the outlet or the circuit in the junction box will be denoted by a green/red light in the cube. Green will denote a correctly wired and installed circuit while the red will denote a cross wired circuit. In addition this handheld electrical testing device 1 can be employed to make sure the appropriate number of outlets or other junction boxes are wired to the tested circuit breaker. This will allow quick discovery of any potentially overloaded circuits since the number of outlets and junctions boxes associated with that circuit breaker are known. It should be noted that it is possible to utilize the handheld electrical testing device 1 to energize a specific circuit associated with an individual breaker by connecting the testing leads 9, 10, 11 to the hot and neutral connected to that particular circuit breaker.

It should be apparent from the foregoing that an invention having significant advantages has been provided. While the invention is shown in only a few of its forms, it is not just limited but is susceptible to various changes and modifications without departing from the spirit thereof.

I claim:

1. A handheld electrical testing device comprising:
a housing;
a display located on the surface of the housing that displays a variety of information, such as the results of an electrical test of an electrical component, whether the battery is good or not, and whether an electrical component has live current;
one or more electrical circuits located inside the housing that enable the handheld electrical testing device to provide a safe amount of current to an electrical component, tests electrical components, and sends results of the electrical test to the display;
a selector switch located on the surface of the housing whereon the selector switch is turned to a certain location which activates certain electrical circuits within the device depending on the test the user desires to run;
a battery compartment wherein a direct current battery can be placed and used to provide power to the device as well as a safe amount of current to an electrical component;
multiple test leads that can be inserted into the housing connected to the internal circuitry within the housing and that can be clamped onto electrical components of a structure to provide a safe amount of current as well as test an electrical component.

2. A handheld electrical testing device according to claim 1 further comprising:
cubes with electrical circuitry that can be plugged into electrical outlets that have been provided a safe amount of current;
cubes that have test leads that can be clamped onto electrical components that have been safely energized by the handheld electrical testing device so that the electrical component can be tested.
